(19) United States
(12) Patent Application Publication
(10) Pub. No.: US 2016/0373144 A1
(43) Pub. Date: Dec. 22, 2016

(54) POWER AMPLIFICATION MODULE

(71) Applicant: Murata Manufacturing Co., Ltd., Kyoto (JP)

(72) Inventor: Kiichiro Takenaka, Kyoto (JP)

(21) Appl. No.: 15/165,375

(22) Filed: May 26, 2016

(30) Foreign Application Priority Data
Jun. 16, 2015 (JP) 2015-120745

(51) Int. Cl. H04B 1/04; H03F 3/45; H03F 3/24; H03F 1/02; H03F 3/193

(52) U.S. Cl. CPC H04B 1/0475; H03F 1/0222; H03F 3/193; H03F 3/245; H03F 3/45179; H03F 3/4508; H03F 2200/102; H03F 2200/105; H03F 2203/45112; H03F 2203/45172; H03F 2200/451; H03F 2200/75; H03F 2200/411; H03F 2200/336; H04B 2001/0408

(57) ABSTRACT

A power amplification module includes: first to fourth differential amplifiers; first to fourth input windings that are respectively connected to differential outputs of the first to fourth differential amplifiers; first to fourth output windings that are respectively electromagnetic-field coupled with the first to fourth input windings; and a bias circuit that controls supply of a bias voltage on the basis of a mode signal. The first to fourth output windings are connected in series with each other. The winding ratio between each input winding and output winding is 2:1. The bias circuit supplies a bias voltage to the first to third differential amplifiers and halts supply of the bias voltage to the fourth differential amplifier in a case of an envelope tracking scheme. The bias circuit supplies the bias voltage to the first to fourth differential amplifiers in a case of an average power tracking scheme.

### BACKGROUND

### Technical Field

The present disclosure relates to a power amplification module.

In a mobile terminal that utilizes a cellular phone communications network, a power amplification module is used in order to amplify the power of a signal to be transmitted to a base station. In recent years, modulation schemes such as high-speed uplink packet access (HSUPA), long term evolution (LTE) and LTE-Advanced, which are high-speed data communication standards, have been adopted in mobile terminals. In these communication standards, it is important that shifting of phase and amplitude be made small in order to improve the communication speed. In other words, high linearity is demanded for a power amplification module. In addition, in these communication standards, the range over which the amplitude of a signal changes (dynamic range) is often wide in order to improve the communication speed. A high power supply voltage is necessary in order to achieve high linearity in the case where the dynamic range is wide and the power consumption of the power amplification module tends to be high.

However, it is demanded that power consumption be reduced in mobile terminals in order to lengthen the amount of time for which telephone calls and communication can be performed. In Japanese Unexamined Patent Application Publication (Translation of PCT Application) No. 2005-513943 for example, an envelope tracking (ET) scheme is disclosed that improves the power efficiency by controlling the power supply voltage of a power amplification module in accordance with the amplitude level of an input modulated signal. In addition, in Japanese Unexamined Patent Application Publication (Translation of PCT Application) No. 2015-512160 for example, an average power tracking (APT) scheme is disclosed that improves the power efficiency by controlling the power supply voltage of a power amplification module in accordance with the average output power.

In the ET scheme, a power supply voltage is considered by a power supply IC that can step up the voltage. This type of power supply IC is called an ET modulator. On the other hand, in the APT scheme, a power supply voltage is considered by a step-down DC-DC converter. Accordingly, the maximum value of the power supply voltage supplied to the power amplification module in a mobile terminal that uses a lithium ion battery is around 4.5 V in the case of the ET scheme and is around 3.4 V in the case of the APT scheme, for example.

A saturated output power P_{OUT} of the power amplification module is P_{OUT}=(½)×(V_{CC}²/R_{L}), where V_{CC} is the power supply voltage and R_{L} is a load impedance. As described above, the maximum value of the power supply voltage V_{CC} is different in the ET scheme and the APT scheme. Consequently, the load impedance R_{L} has to be changed in the ET scheme and the APT scheme in order to obtain the same maximum output power in the ET scheme and the APT scheme. Therefore, ET-scheme power amplification modules and APT-scheme power amplification modules have to be individually designed.

### BRIEF SUMMARY

The present disclosure was made in light of the above-described circumstances to provide a power amplification module that supports both the ET scheme and the APT scheme.

A power amplification module according to an embodiment of the present disclosure includes: first to fourth differential amplifiers that are differentially input with a radio frequency signal and that differentially output an amplified signal obtained by amplifying the radio frequency signal; a first input winding that is connected to differential outputs of the first differential amplifier; a second input winding that is connected to differential outputs of the second differential amplifier; a third input winding that is connected to differential outputs of the third differential amplifier; a fourth input winding that is connected to differential outputs of the fourth differential amplifier; a first output winding that is electromagnetic-field coupled with the first input winding; a second output winding that is electromagnetic-field coupled with the second input winding; a third output winding that is electromagnetic-field coupled with the third input winding; a fourth output winding that is electromagnetic-field coupled with the fourth input winding; and a bias circuit that controls supply of a bias voltage to the first to fourth differential amplifiers on the basis of a mode signal that represents an operation mode. The first to fourth output windings are connected in series with each other. The winding ratio between each electromagnetic-field coupled input winding and output winding is 2:1. The bias circuit supplies a bias voltage to the first to third differential amplifiers and halts supply of the bias voltage to the fourth differential amplifier in a case where the operation mode is an envelope tracking scheme. The bias circuit supplies the bias voltage to the first to fourth differential amplifiers in a case where the operation mode is an average power tracking scheme.

According to the embodiment of the present disclosure, by controlling the output impedance of differential amplifiers, a power amplification module can be provided that supports both an ET scheme and an APT scheme.

Other features, such as elements, characteristics, and advantages of the present disclosure will become more apparent from the following detailed description of embodiments of the present disclosure with reference to the attached drawings.

### BRIEF DESCRIPTION OF THE SEVERAL VIEWS OF THE DRAWINGS

FIG. 1 illustrates an example configuration of a transmission unit that includes a power amplification module according to an embodiment of the present disclosure;

FIG. 2 illustrates an example configuration of a power supply circuit;

FIG. 3 illustrates an example configuration of a power amplification module;

FIG. 4A illustrates the state of output matching in the case of an ET scheme;

FIG. 4B illustrates the state of output matching in a configuration obtained by realizing the configuration illustrated in FIG. 4A by using a common-emitter (or common-source) amplification circuit.

FIG. 5A illustrates an output matching state in the case of an APT scheme;

FIG. 5B illustrates an output matching state in a configuration obtained by realizing the configuration illustrated in FIG. 5A by using a common-emitter (or common-source) amplification circuit.

### DETAILED DESCRIPTION

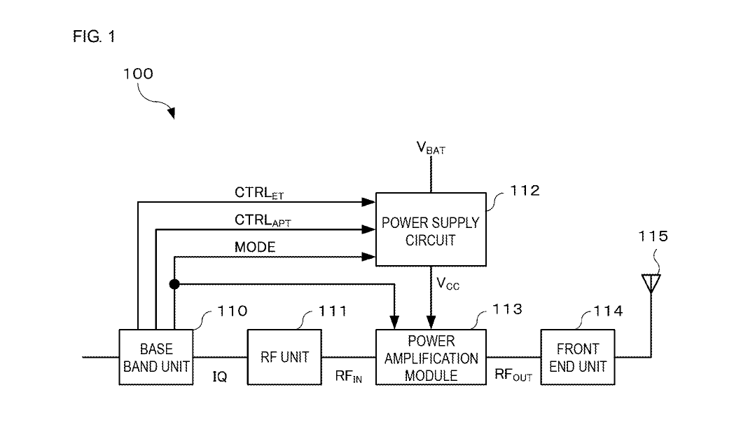

Hereafter, an embodiment of the present disclosure will be described while referring to the drawings. FIG. 1 illustrates an example configuration of a transmission unit that includes a power amplification module according to an embodiment of the present disclosure. A transmission unit 100 is for example used in a mobile communication device such as a cellular phone in order to transmit various signals such as speech and data to a base station. The transmission unit 100 of this embodiment handles a plurality of frequency bands (multiple bands) among radio frequencies (RF). Although such a mobile communication device would also be equipped with a reception unit for receiving signals from the base station, the description of such a reception unit is omitted here.

As illustrated in FIG. 1, the transmission unit 100 includes a base band unit 110, an RF unit 111, a power supply circuit 112, a power amplification module 113, a front end unit 114, and an antenna 115.

The base band unit 110 modulates an input signal such as speech or data on the basis of a modulation scheme such as HSUPA or LTE and outputs a modulated signal. In this embodiment, the modulated signal output from the base band unit 110 is output as IQ signals (I signal and Q signal) where the amplitude and the phase are represented on an IQ plane. The frequencies of the IQ signals are on the order of several MHz to several tens of MHz, for example.

In addition, the base band unit 110 outputs a mode signal MODE that specifies the operation mode of the power amplification module 113. In this embodiment, the power amplification module 113 can operate using an ET scheme (first scheme) and an APT scheme (second scheme). For example, the base band unit 110 can output a mode signal MODE that specifies the ET scheme in a case where the output of the power amplification module 113 is at a predetermined level or higher and can output a mode signal MODE that specifies the APT scheme in a case where the output of the power amplification module 113 is lower than the predetermined level. In addition, for example, the base band unit 110 can output a mode signal MODE that specifies the ET scheme in the case of a frequency band for which the effect of noise from the power supply circuit 112 would be comparatively small at the time of operation of the ET scheme and can output a mode signal MODE that specifies the APT scheme in the case of a frequency band for which the effect of noise from the power supply circuit 112 would be comparatively large at the time of operation of the ET scheme.

In addition, the base band unit 110 outputs control signals for controlling the power supply voltage in accordance with the operation scheme of the power amplification module. Specifically, for example, in the case of the ET scheme, the base band unit 110 detects the amplitude level of the modulated signal on the basis of the IQ signals, and outputs a power supply control signal CTRL_{ET} to the power supply circuit 112 so that a power supply voltage V_{CC} supplied to the power amplification module 113 comes to have a level that corresponds to the envelope (amplitude level) of an RF signal. In addition, for example, in the case of the APT scheme, the base band unit 110 outputs a power supply control signal CTRL_{APT} to the power supply circuit 112 so that the power supply voltage V_{CC} supplied to the power amplification module 113 comes to have a level that corresponds to the average output power of the power amplification module 113.

The RF unit 111 generates an RF signal (RF_{IN}), which is for performing wireless transmission, from the IQ signals output from the base band unit 110. The RF signal has a frequency of around several hundred MHz to several GHz, for example. In the RF unit 111, the IQ signals may be converted into an intermediate frequency (IF) signal and an RF signal may be then generated from the IF signal, instead of directly converting the IQ signals into the RF signal.

The power supply circuit 112 generates a power supply voltage V_{CC} having a level that corresponds to the operation scheme from a battery voltage V_{BAT} on the basis of the mode signal MODE and the power supply control signal CTRL_{ET} or CTRL_{APT} and supplies the generated power supply voltage V_{CC} to the power amplification module 113. Specifically, the power supply circuit 112 generates a power supply voltage V_{CC} that corresponds to the power supply control signal CTRL_{ET} in the case of the ET scheme. Furthermore, the power supply circuit 112 generates a power supply voltage V_{CC} that corresponds to the power supply control signal CTRL_{APT} in the case of the APT scheme. The power supply circuit 112 will be described in detail later.

The power amplification module 113 amplifies the power of the RF signal (RF_{IN}) output from the RF unit 111 on the basis of the power supply voltage V_{CC} supplied from the power supply circuit 112 up to the level that is required to transmit the RF signal to a base station and outputs an amplified signal (RF_{OUT}). The power amplification module 113 will be described in detail later.

The front end unit 114 performs filtering on the amplified signal (RF_{OUT}) and switching on a reception signal received from the base station. The amplified signal output from the front end unit 114 is transmitted to the base station via the antenna 115.

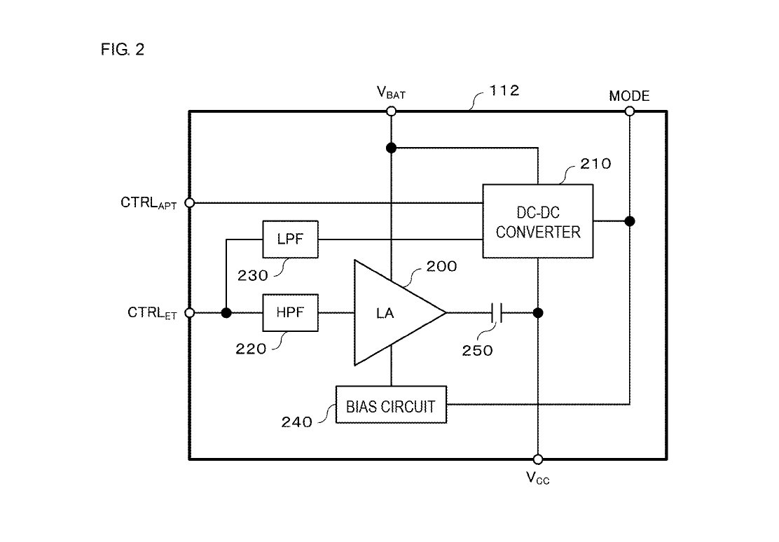

FIG. 2 illustrates an example configuration of the power supply circuit 112. As illustrated in FIG. 2, the power supply circuit 112 includes a linear amplifier (LA) 200, a DC-DC converter 210, a high pass filter (HPF) 220, a low pass filter (LPF) 230, a bias circuit 240 and a capacitor 250.

The linear amplifier 200 is supplied with the battery voltage VBAT as a power supply voltage and outputs an output voltage obtained by linearly amplifying an input signal.

The DC-DC converter 210 is supplied with the battery voltage VBAT as an input voltage, steps down the input voltage and then outputs the stepped down voltage. Specifically, in the case of the ET scheme, the DC-DC converter 210 outputs a voltage that corresponds to the power supply control signal CTRL_{ET}. Furthermore, in the case of the APT scheme, the DC-DC converter 210 outputs a voltage that corresponds to the power supply control signal CTRL_{APT}.

The high pass filter 220 is a filter that allows high frequency components of the power supply control signal CTRL_{ET} to pass therethrough. In addition, the low pass filter 230 is a filter that allows low frequency components of the power supply control signal CTRL_{ET} to pass therethrough. The power supply control signal CTRL_{ET} is a signal that corresponds to the envelope of the RF signal (RF_{IN}).

The bias circuit 240 supplies a bias voltage to the linear amplifier 200. The bias circuit 240 supplies a bias voltage in the case of the ET scheme and stops supplying the bias voltage in the case of the APT scheme.

The capacitor 250 serves a combining circuit that combines the voltage output from the linear amplifier 200 and the voltage output from the DC-DC converter 210.

An example of operation of the power supply circuit 112 will be described.

In the case of the ET scheme, the bias circuit 240 supplies a bias voltage to the linear amplifier 200. Therefore, both the linear amplifier 200 and the DC-DC converter 210 operate. The linear amplifier 200 outputs a voltage that corresponds to the power supply control signal CTRL_{ET} input via the high pass filter 220. In addition, the DC-DC converter 210 outputs a voltage that corresponds to the power supply control signal CTRL_{ET} input via the low pass filter 230. The voltage output from the linear amplifier 200 and the voltage output from the DC-DC converter 210 are combined by the capacitor 250 and the combined voltage is output as a power supply voltage V_{CC} that corresponds to the envelope of the RF signal (RF_{IN}). The range of the power supply voltage V_{CC} output in the case of the ET scheme is around 0.5 V to 4.5 V.

In the case of the APT scheme, the bias circuit 240 halts supply of the bias voltage to the linear amplifier 200. Therefore, the linear amplifier 200 does not operate and only the DC-DC converter 210 operates. The DC-DC converter 210 outputs a voltage that corresponds to the power supply control signal CTRL_{APT}. The voltage output from the DC-DC converter 210 is output as a power supply voltage V_{CC} that corresponds to the average output power. The range of the power supply voltage V_{CC} output in the case of the APT scheme is around 0.5 V to 3.4 V.

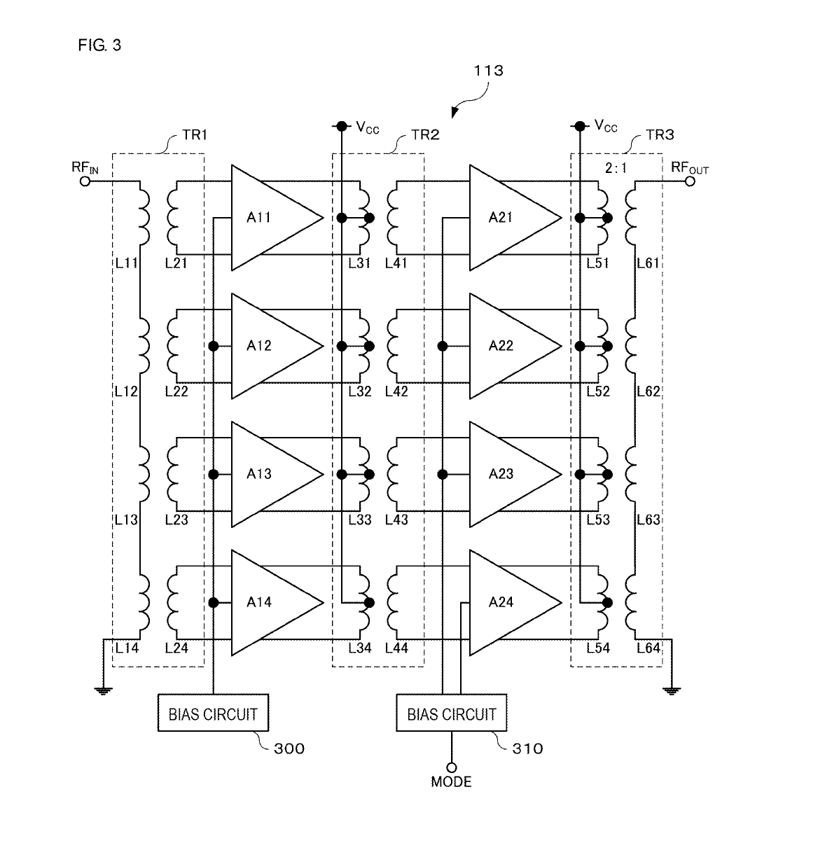

FIG. 3 illustrates an example configuration of the power amplification module 113. As illustrated in FIG. 3, the power amplification module 113 includes differential amplifiers A11 to A14 and A21 to A24, transformers TR1, TR2 and TR3 and bias circuits 300 and 310.

Each of the differential amplifiers A11 to A14 and A21 to A24 includes a differential pair of transistors and differentially outputs an amplified signal obtained by amplifying a signal differentially input to the differential pair of transistors. The transistors may be FETs or may be bipolar transistors (for example, heterojunction bipolar transistors (HBTs)).

The differential inputs of the differential amplifiers A11 to A14 are connected to output windings L21 to L24 of the transformer TR1. In addition, the differential outputs of the differential amplifiers A11 to A14 are connected to input windings L31 to L34 of the transformer TR2. Similarly, the differential inputs of the differential amplifiers A21 to A24 (first to fourth differential amplifiers) are connected to output windings L41 to L44 of the transformer TR2. In addition, the differential outputs of the differential amplifiers A21 to A24 are connected to input windings L51 to L54 of the transformer TR3.

The transformer TR1 includes input windings L11, L12, L13 and L14 and output windings L21, L22, L23 and L24. The input windings L11 to L14 are connected in series with each other, the RF signal (RF_{IN}) is input to one end of the input winding L11 and one end of the input winding L14 is grounded. The input winding L11 and the output winding L21 are electromagnetic-field coupled with each other. Similarly, the input windings L12 to L14 and the output windings L22 to L24 are also respectively electromagnetic-field coupled with each other. Therefore, in the transformer TR1, the RF signal (RF_{IN}) input to the input windings L11 to L14 is output by the output windings L21 to L24.

The transformer TR2 includes input windings L31, L32, L33 and L34 and output windings L41, L42, L43 and L44. The input winding L31 and the output winding L41 are electromagnetic-field coupled with each other. Similarly, the input windings L32 to L34 and the output windings L42 to L44 are also respectively electromagnetic-field coupled with each other. Therefore, in the transformer TR2, an RF signal corresponding to the RF signal input to the input windings L31 to L34 is output by the output windings L41 to L44. The power supply voltage V_{CC}, which is supplied to the differential amplifiers A11 to A14, is applied to the center points of the input windings L31 to L34.

The transformer TR3 includes input windings L51, L52, L53 and L54 (first to fourth input windings) and output windings L61, L62, L63 and L64 (first to fourth output windings). The output windings L61 to L64 are connected in series with each other and one end of the output winding L64 is grounded. The input winding L51 and the output winding L61 are electromagnetic-field coupled with each other. Similarly, the input windings L52 to L54 and the output windings L62 to L64 are also respectively electromagnetic-field coupled with each other. Therefore, in the transformer TR3, an RF signal (RF_{OUT}) corresponding to the RF signal input to the input windings L51 to L54 is output from one end of the output winding L61. The power supply voltage V_{CC}, which is supplied to the differential amplifiers A21 to A24, is applied to the center points of the input windings L51 to L54. In addition, the winding ratios between the input windings L51 to L54 and the output windings L61 to L64 are 2:1.

The bias circuit 300 supplies a bias voltage to the differential amplifiers A11 to A14. Specifically, in the case where the transistors that form the differential amplifiers are FETs, the bias circuit 300 supplies the bias voltage to the gates of the FETs. In addition, in the case where the transistors that form the differential amplifiers are, for example, bipolar transistors, the bias circuit 300 supplies the bias voltage to the bases of the bipolar transistors.

Similarly to the bias circuit 300, the bias circuit 310 supplies a bias voltage to the differential amplifiers A21 to A24. However, the bias circuit 310 controls the supply of the bias voltage on the basis of the mode signal MODE. Specifically, in the case of the ET scheme, the bias circuit 310 supplies the bias voltage to the differential amplifiers A21 to A23 and halts supply of the bias voltage to the differential amplifier A24. In addition, in the case of the APT scheme, the bias circuit 310 supplies the bias voltage to the differential amplifiers A21 to A24.

The power amplification module 113 forms a two-stage amplification circuit with the above-described configuration. That is, the differential amplifiers A11 to A14 form a first-stage (driver-stage) amplification circuit and the differential amplifiers A21 to A24 form a second-stage (output-stage) amplification circuit. With this configuration, the power amplification module 113 outputs an amplified signal (RF_{OUT}) obtained by amplifying the RF signal (RF_{IN}). The number of stages of the amplification circuit of the power amplification module 113 is not limited to two and may be one or three or more. However, control of the supply of the bias voltage by the bias circuit 310 is performed in the final-stage amplification circuit regardless of the number of stages.

In the power amplification module 113, the transformer TR1 forms a matching circuit that realizes matching between the input of the power amplification module 113 and the input of the first-stage amplification circuit. Similarly, the transformer TR2 forms a matching circuit that realizes matching between the output of the first-stage amplification circuit and the input of the second-stage amplification circuit. The transformer TR3 forms a matching circuit (output matching) that realizes matching between the output of the second-stage amplification circuit and the output of the power amplification module 113.

Next, description will be given of load impedance in the power amplification module 113.

First, load impedance in the case of the ET scheme will be described.

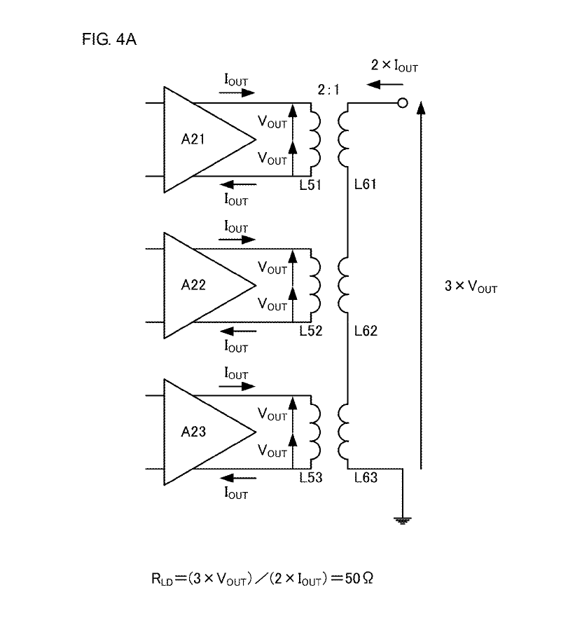

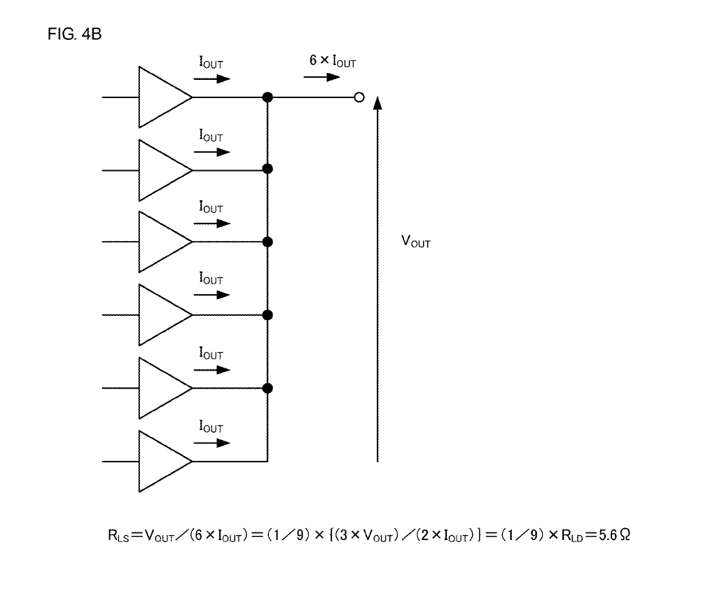

FIG. 4A illustrates the state of output matching in the case of the ET scheme. In the case of the ET scheme, the bias voltage is not supplied to the differential amplifier A24 and therefore three differential amplifiers, namely, the differential amplifiers A21 to A23 operate. Here, when V_{OUT} is the output voltage and I_{OUT} is the output current of each of the differential outputs of the differential amplifiers, the voltage and the current input to the primary side of each transformer are 2×V_{OUT} and I_{OUT}, respectively. From the relational expression N2/N1=V2/V1=I1/I2 between the winding ratio (N1:N2), the voltage transformation ratio (V1:V2) and the current transformation ratio (I1:I2) of each transformer, the voltage and the current output from the secondary side are V_{OUT} and 2×I_{OUT}, respectively, due to the transformation in each transformer having a winding ratio of 2:1. At the secondary side, three windings are connected in series with each other and therefore the output voltage is 3×V_{OUT} and the output current is 2×I_{OUT}. Therefore, the load impedance R_{LD} in this configuration is R_{LD}=(3×V_{OUT})/(2×I_{OUT}).

FIG. 4B illustrates the state of output matching in a configuration obtained by realizing the configuration illustrated in FIG. 4A by using a common-emitter (or common-source) amplification circuit. In this configuration, the output voltage is V_{OUT} and the output current is 6×I_{OUT}. Therefore, a load impedance R_{LS} obtained through conversion for a common-emitter (or common-source) amplification circuit is R_{LS}=V_{OUT} (6×I_{OUT})=( 1/9)×{(3×V_{OUT})/(2×I_{OUT})}=( 1/9)×R_{LD}. Therefore, R_{LS} is around 5.6Ω when R_{LD} is 50Ω.

Next, load impedance in the case of the APT scheme will be described.

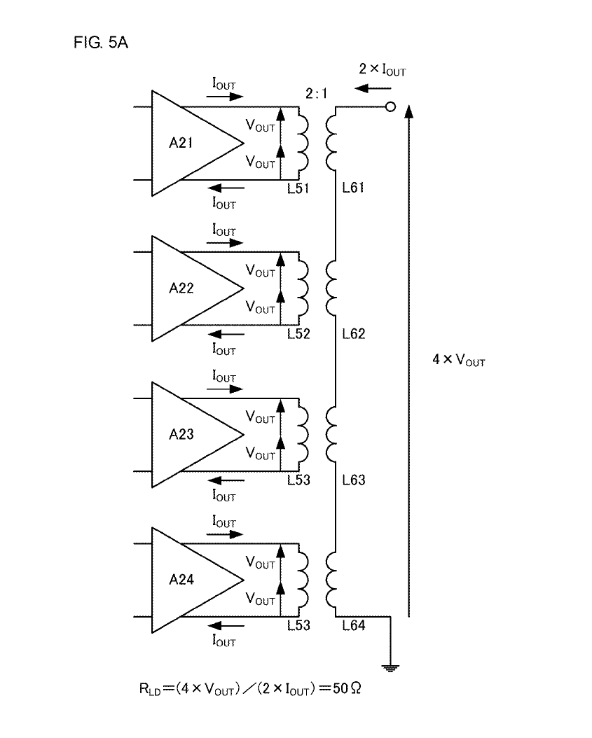

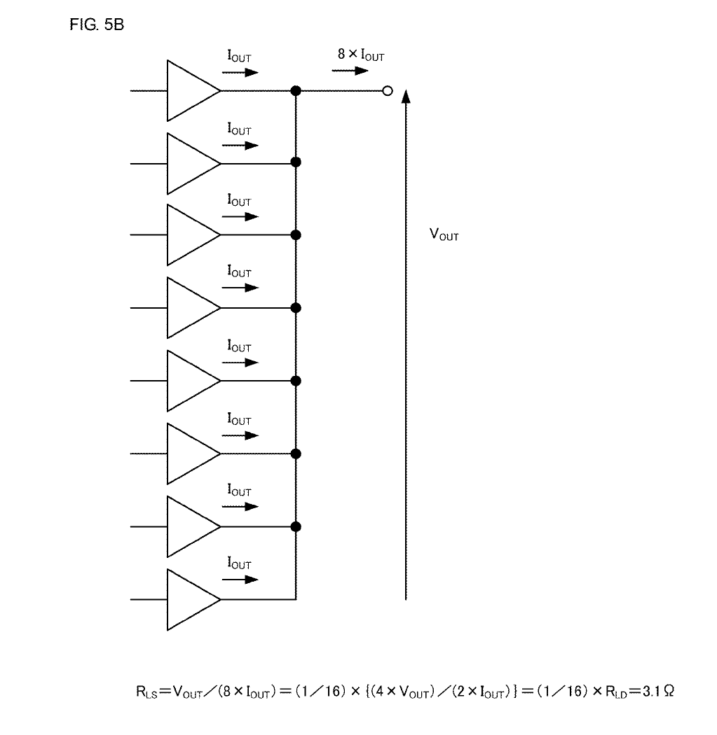

FIG. 5A illustrates the state of output matching in the case of the APT scheme. Four differential amplifiers, namely, the differential amplifiers A21 to A24 operate in the case of the APT scheme. Similarly to as in the case illustrated in FIG. 4A, when V_{OUT} is the output voltage and I_{OUT} is the output current of each of the differential outputs of the differential amplifiers, the voltage and the current input to the primary side of each transformer are 2×V_{OUT} and I_{OUT}, respectively. The voltage and the current output from the secondary side are V_{OUT} and 2×I_{OUT}, respectively, from the transformation in the transformer having a winding ratio of 2:1. At the secondary side, four windings are connected in series with each other and therefore the output voltage is 4×V_{OUT} and the output current is 2×I_{OUT}. Therefore, the load impedance R_{LD} in this configuration is R_{LD}=(4×V_{OUT})/(2×I_{OUT}).

FIG. 5B illustrates the state of output matching in a configuration obtained by realizing the configuration illustrated in FIG. 5A by using a common-emitter (or common-source) amplification circuit. In this configuration, the output voltage is V_{OUT} and the output current is 8×I_{OUT}. Therefore, a load impedance R_{LS} obtained through conversion for a common-emitter (or common-source) amplification circuit is R_{LS}=V_{OUT} (8×I_{OUT})=( 1/16)×{(4×V_{OUT})/(2×I_{OUT})}=( 1/16)×R_{LD}. Therefore, R_{LS} is around 3.1Ω when R_{LD} is 50Ω.

As described above, the load impedance obtained through conversion for a common-emitter (or common-source) amplification circuit in the power amplification module 113 is around 5.6Ω with the ET scheme and around 3.1Ω with the APT scheme. Taking the maximum value of the power supply voltage V_{CC} to be 4.5 V in the ET scheme and 3.4 V in the APT scheme, the maximum value of the saturated output power P_{OUT} is around 32.7 dBm in the ET scheme and around 32.6 dBm in the APT scheme. That is, the maximum output powers can be made substantially the same in the ET scheme and the APT scheme in the power amplification module 113.

Taking an increase in the peak power due to the modulated signal to be 4.5 dB and loss due to output matching to be 1 dB at the maximum output power, the average output power is around 27 dBm. Therefore, loss up to the antenna of 4 dB is permissible and is appropriate for design of cellular phones.

An exemplary embodiment of the present disclosure has been described above. According to the power amplification module 113, the bias voltage is supplied to the differential amplifiers A21 to A23 and supply of the bias voltage to the differential amplifier A24 is halted in the case of the ET scheme. In addition, in the case of the APT scheme, the bias voltage is supplied to the differential amplifiers A21 to A24. Thus, by controlling supply of the bias voltage, the load impedance can be adjusted in conversion for a common-emitter (or common-source) amplification circuit and the maximum output power can be made substantially the same in both the ET scheme and the APT scheme by using the same power amplification module 113.

Thus, with the power amplification module 113, the ET scheme and the APT scheme can be switched between using the mode signal MODE. Therefore, for example, in a case where the effect of noise due to the ET scheme is a concern for a frequency band where a reception band and a transmission band are close to each other, operation can be performed in which the APT scheme is used for that frequency band and the ET scheme is used for the other frequency band.

Furthermore, the power supply circuit 112 is used in both the ET scheme and the APT scheme in the transmission unit 100 of this embodiment. Therefore, there is no need to individually provide power supply circuits and an increase in the scale of the circuit can be suppressed. In addition, since operation of the linear amplifier 200 is halted in the case of the APT scheme, an increase in power consumption can be suppressed.

The purpose of the embodiment described above is to enable easy understanding of the present disclosure and the embodiment is not to be interpreted as limiting the present disclosure. The present disclosure can be modified or improved without necessarily departing from the gist of the disclosure and equivalents to the present disclosure are also included in the present disclosure. In other words, appropriate design changes made to the embodiment by one skilled in the art are included in the scope of the present disclosure so long as the changes have the characteristics of the present disclosure. For example, the elements included in the embodiment and the arrangements, materials, conditions, shapes, sizes and so forth of the elements are not limited to those exemplified in the embodiment and can be appropriately changed. In addition, the elements included in the embodiment can be combined as much as technically possible and such combined elements are also included in the scope of the present disclosure so long as the combined elements have the characteristics of the present disclosure.

While embodiments of the disclosure have been described above, it is to be understood that variations and modifications will be apparent to those skilled in the art without necessarily departing from the scope and spirit of the disclosure. The scope of the disclosure, therefore, is to be determined solely by the following claims.

What is claimed is:

1. A power amplification module comprising:
first, second, third, and fourth differential amplifiers that are differentially inputted with a radio frequency signal and that differentially output an amplified signal obtained by amplifying the radio frequency signal;
a first input winding that is connected to differential outputs of the first differential amplifier;
a second input winding that is connected to differential outputs of the second differential amplifier;
a third input winding that is connected to differential outputs of the third differential amplifier;
a fourth input winding that is connected to differential outputs of the fourth differential amplifier;
a first output winding that is electromagnetic-field coupled with the first input winding;
a second output winding that is electromagnetic-field coupled with the second input winding;
a third output winding that is electromagnetic-field coupled with the third input winding;
a fourth output winding that is electromagnetic-field coupled with the fourth input winding; and
a bias circuit that controls supply of a bias voltage to the first, second, third, and fourth differential amplifiers on the basis of a mode signal that represents an operation mode;
wherein the first, second, third, and fourth output windings are connected in series with each other, and
wherein the bias circuit
supplies the bias voltage to the first, second, and third differential amplifiers and halts supply of the bias voltage to the fourth differential amplifier when the operation mode is a first scheme that controls a power supply voltage in accordance with an amplitude level of the radio frequency signal, and
supplies the bias voltage to the first, second, third, and fourth differential amplifiers when the operation mode is a second scheme that controls the power supply voltage in accordance with an average output power.

2. The power amplification module according to claim 1, wherein
a winding ratio between the first input winding and the first output winding is 2:1,
a winding ratio between the second input winding and the second output winding is 2:1,
a winding ratio between the third input winding and the third output winding is 2:1, and
a winding ratio between the fourth input winding and the fourth output winding is 2:1.

3. A transmission unit comprising:
the power amplification module according to claim 1; and
a power supply circuit that supplies the power supply voltage to the first to fourth differential amplifiers;
wherein the power supply circuit includes a DC-DC converter and a linear amplifier, and
generates a power supply voltage that corresponds to the amplitude level of the radio frequency signal by using the DC-DC converter and the linear amplifier in the case of the first scheme, and
generates a power supply voltage that corresponds to the average output power by using the DC-DC converter in the case of the second scheme.

4. The transmission unit according to claim 3 further comprising:
a first power supply control signal and a second power supply control signal;
a high pass filter; and
a low pass filter,
wherein the first power supply control signal is input to the linear amplifier via the high pass filter and is input to the DC-DC converter via the low pass amplifier.

5. The transmission unit according to claim 4, wherein the first power supply control signal corresponds to an envelope of the radio frequency signal.

6. The transmission unit according to claim 3, wherein in the case of the first scheme, the power supply voltage is 0.5 V to 4.5 V.

7. The transmission unit according to claim 3, wherein in the case of the second scheme, the power supply voltage is 0.5 V to 3.4 V.

8. A transmission unit comprising:
the power amplification module according to claim 2; and
a power supply circuit that supplies the power supply voltage to the first to fourth differential amplifiers;
wherein the power supply circuit includes a DC-DC converter and a linear amplifier, and
generates a power supply voltage that corresponds to the amplitude level of the radio frequency signal by using the DC-DC converter and the linear amplifier in the case of the first scheme, and
generates a power supply voltage that corresponds to the average output power by using the DC-DC converter in the case of the second scheme.

9. The transmission unit according to claim 8 further comprising:
a first power supply control signal and a second power supply control signal;
a high pass filter; and
a low pass filter,
wherein the first power supply control signal is input to the linear amplifier via the high pass filter and is input to the DC-DC converter via the low pass amplifier.

10. The transmission unit according to claim 9, wherein the first power supply control signal corresponds to an envelope of the radio frequency signal.

11. The transmission unit according to claim 8, wherein in the case of the first scheme, the power supply voltage is 0.5 V to 4.5 V.

12. The transmission unit according to claim 8, wherein in the case of the second scheme, the power supply voltage is 0.5 V to 3.4 V.

13. The transmission unit according to claim 1, wherein the first, second, third and fourth differential amplifiers include a differential pair of heterojunction bipolar transistors.

14. The transmission unit according to claim 1, wherein the first, second, third and fourth differential amplifiers include a differential pair of field effect transistors.

15. A power amplification module according to claim 1, wherein the power amplification module forms a two-stage amplification circuit.

16. A power amplification module according to claim 15, wherein a first-stage amplification circuit of the two-stage amplification circuit comprises field effect transistors and wherein a second-stage amplification circuit of the two-stage amplification circuit comprises bipolar transistors.

17. A power amplification module according to claim 15, wherein a first-stage amplification circuit of the two-stage amplification circuit comprises bipolar transistors and wherein a second-stage amplification circuit of the two-stage amplification circuit comprises field effect transistors.

18. The transmission unit according to claim 3,
wherein the power amplification module forms a two-stage amplification circuit.

19. The transmission unit according to claim 18, wherein a first-stage amplification circuit of the two-stage amplification circuit comprises field effect transistors and wherein a second-stage amplification circuit of the two-stage amplification circuit comprises bipolar transistors.

20. The transmission unit according to claim 18, wherein a first-stage amplification circuit of the two-stage amplification circuit comprises bipolar transistors and wherein a second-stage amplification circuit of the two-stage amplification circuit comprises field effect transistors.
